(19) United States
(12) Patent Application Publication
(10) Pub. No.: US 2007/0247939 A1
(43) Pub. Date: Oct. 25, 2007

(54) MRAM ARRAY WITH REFERENCE CELL ROW AND METHOF OF OPERATION

(76) Inventors: Joseph J. Nahas, Austin, TX (US); Thomas W. Andre, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/379,598

(22) Filed: Apr. 21, 2006

(51) Int. Cl. G11C 11/00; G11C 8/00; G11C 7/02

(52) U.S. Cl. 365/208; 365/158; 365/230.06; 365/189.09

(57) ABSTRACT

A magnetoresistive random access memory (MRAM) avoids difficulties with write disturb by electrically isolating the portion of the array with data from the portion with reference signals while providing fast read speeds by simultaneously enabling the word line having the reference cells and the selected word line. For high speed accessing it is difficult to completely stabilize a precharge prior to beginning the next access. Accordingly, it is desirable for the reference cell and the selected cell to have the same response characteristics because no voltages are truly stationary during high speed accessing. This is achieved by simultaneous accessing and by having matched impedances. Thus, the voltage separation between the reference cell and the selected cell can be maintained even when both are moving even if they are moving in the same direction.

### FIELD OF THE INVENTION

This invention relates to Magnetoresistive Random Access Memories (MRAMs), and more particularly to a MRAM having a row of reference cells.

### BACKGROUND OF THE INVENTION

A magnetoresistive random access memory (MRAM) is a type of non-volatile memory that stores logic states by changing the polarization of one or more magnetic layers which, in turn, changes the resistance of the memory cells. In a MRAM cell, magnetic fields are applied to a magnetic tunnel junction (MJT) to rotate its polarization. Two perpendicular lines lying above and below the cell deliver currents that create the magnetic fields for switching the bit. FIG. 1 illustrates an example of a sequence of currents used to change the state of the bit. In one type of cell this method does not directly write a high or low state, but “toggles” the present state to the opposite state. Repeating the sequence of signals with the same cell will then write the previous state.

For a MRAM device, the stability of the nonvolatile memory state, the repeatability of the read/write cycles, and the memory element-to-element switching field uniformity are three of the most important aspects of its design characteristics. A memory state in a MRAM is not maintained by power, but rather by the direction of the magnetic moment vector. Reading data stored in the memory is accomplished by sensing differences in the MTJ resistance. Typically, the stored state of a memory cell is determined by comparing the cell state to that of a reference cell. Usually, a low resistance bit is designated as a logic “0” while a high resistance bit is designated as a logic “1”. FIG. 2 illustrates, in schematic diagram form, a MRAM array 100 in accordance with one embodiment of the prior art. MRAM array 100 includes rows 102, 104, and 106, data columns 108 and 110, and reference columns 112 and 114. The array includes representative cells 116, 118, 120, 122, 124, 126, 128, 130, 132, 134, 136, and 138. Cells 122, 124, 126, 128, 130, and 132 function as reference cells, but are of the same construction as the normal data storing cells. Each cell includes a select transistor and a MTJ. For example, cell 118 includes N-channel select transistor 117 and MTJ 119. A drain electrode of transistor 117 is coupled to a read bit line labeled “RBL0”, a gate electrode is coupled to a read word line labeled “RWL1”, and a source electrode is coupled to a first terminal of MJT 119. A second terminal of MJT 119 is coupled to a power supply terminal labeled “VSS”. Each of the other transistors has similar connections. In reference column 112, reference cells 122, 124, and 126 have drain terminals coupled to a high reference write bit line labeled “WBLH”. In reference column 114, each of reference cells 128, 130, and 132 have a drain terminal coupled to a low reference write bit line labeled “WBLL”. All of the cells in column 112 are written with a high logic state and all of the cells in column 114 are written with a low logic state. Write bit lines are labeled “WBL0” and “WBLN” and are coupled to a power supply terminal labeled “VDD”. As illustrated in FIG. 2, the write bit lines cross over the MJTs of each column. Write word lines labeled “WWL0”—“WWL2” cross over the MJTs of each row. When reading the state of the cell, the cell current is compared to the current on the high reference bit line labeled “RBLH” and to the current on the low reference bit line labeled “RBLL” to determine the stored logic state. When writing to a cell, currents through selected write word lines and selected write bit lines cause the cell to change logic stages. For example, cell 118 is toggled by providing a write word line current pulse labeled “I_{X}” and a write bit line current pulse labeled “I_{Y}” as illustrated in FIG. 1. However, when writing to a cell, all of the other MTJs in the row, for example row 104, receive the magnetic field generated by the write word line current pulse I_{X}. If a bit in the row has a very low switching threshold, thermal fluctuations during the write word line current pulse I_{X} may cause the bit to inadvertently toggle states. If the bit that toggles is one of the reference bits, such as for example, reference cells 124 and 130, then the sense amplifier will no longer function properly for that row. Also, the polarization of the reference MTJ can never be corrected by error correction code (ECC) in the memory as ordinary bits may eventually be corrected leaving the memory in a vulnerable state. Therefore, there is a need to reduce the probability of one of the reference bits inadvertently toggling states.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the following drawings:

FIG. 1 illustrates a timing diagram of the currents used to toggle a MRAM cell.

FIG. 2 illustrates, in schematic diagram form, a MRAM array in accordance with one embodiment of the prior art.

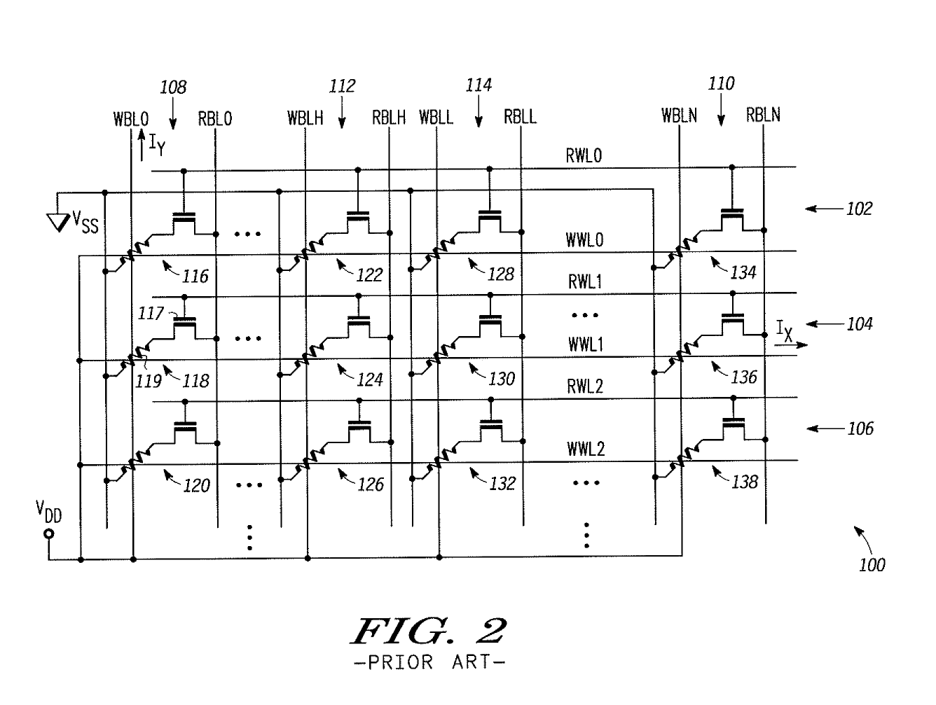

FIG. 3 illustrates, in schematic diagram form, a MRAM array in accordance with an embodiment of the present invention.

FIG. 4 illustrates, in schematic diagram form, a MRAM array in accordance with another embodiment of the present invention.

FIG. 5 illustrates, in block diagram form, a MRAM having the array of FIG. 3 or FIG. 4.

FIG. 6 illustrates a timing diagram of various signals in the MRAM of FIG. 5.

### DETAILED DESCRIPTION OF THE PREFERRED EMBODIMENT

Generally, the present invention provides a MRAM integrated circuit having an array with a reduced probability of a disturbed a reference cell. In one embodiment the MRAM array has a row of reference cells. One cell of the row is used as a “high” reference during read operation and another reference cell of the row is used as a “low” reference during a read operation. All of the other cells of the reference row are disabled from functioning as a memory cell. For example, in one illustrated embodiment, the select transistor of each unused reference cell is disconnected from its MJT. In another embodiment, the gates of the unused reference cells are coupled to ground. However, the disabled cells still serve the purpose of keeping the bit line capacitance balanced for all of the bit lines. By providing a dedicated row of reference cells, a write operation does not subject the reference cells to a current pulse that is intended for changing the logic state of a selected cell. Also, when reading a selected cell, the read word line signal for the selected cell is asserted simultaneously with the read word line signal for the reference cell. This allows a voltage separation between the reference cell and the selected cell to be maintained even when both voltages are moving in the same direction.

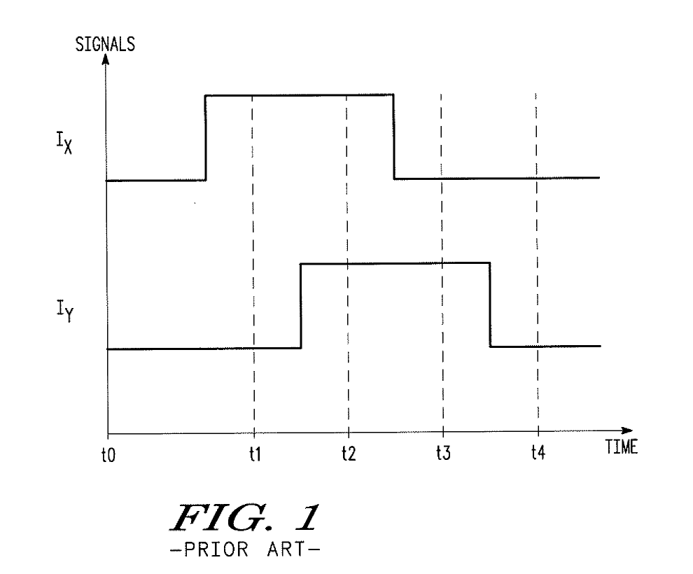

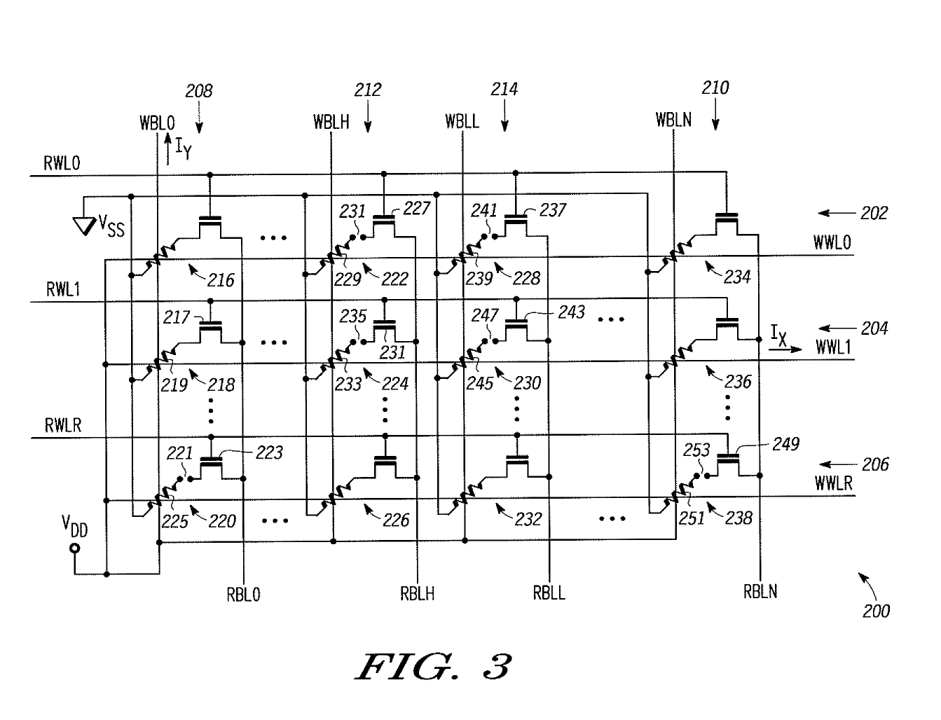

FIG. 3 illustrates, in schematic diagram form, MRAM array 200 in accordance with an embodiment of the present invention. MRAM array 200 includes rows 202, 204, and 206, data columns 208 and 210, and reference columns 212 and 214. The array 200 includes representative cells 216, 218, 220, 222, 224, 226, 228, 230, 232, 234, 236, and 238. Each cell includes a select transistor and a MTJ. For example, cell 218 includes N-channel select transistor 217 and MTJ 219. A drain electrode of transistor 217 is coupled to a read bit line labeled “RBL0”, a gate electrode is coupled to a read word line labeled “RWL1”, and a source electrode coupled to a first terminal of the MJT 219. A second terminal of MJT 219 is coupled to a power supply terminal labeled “VSS”. Each of the other transistors has similar connections. Write bit lines are labeled “WBL0” and “WBLN” are coupled to a power supply terminal labeled “VDD” and cross over the MJTs of each column. Write word lines are labeled “WWL0” and “WWL1” cross over the MJTs of each row. When writing to a cell, currents through selected write word lines and selected write bit lines cause the cell to change logic stages,. For example, cell 218 is toggled by providing a write word line current pulse labeled “I_{X}” and a write bit line current pulse labeled “I_{Y}” in sequence as illustrated in FIG. 1. Note that the illustrated embodiment described a cell that uses a toggling type of write operation. In other embodiments the memory cells can be a different type of MRAM cell that uses a different type of write operation. Also, in the illustrated embodiment, VDD is coupled to receive a positive power supply voltage and VSS is coupled to ground. In other embodiments, the power supply voltages may be different.

In column 212 the cells 222, 224, and 226 have drain terminals coupled to a high reference bit line labeled “RBLH”, and a MJT terminal coupled to ground (VSS). A reference write word line labeled “WWLR” crosses over each cell of the reference row 206 for supplying one write current. In column 214, the cells 228, 230, and 232 have terminals coupled to a low reference bit line labeled “RBLL”, and a MJT terminal coupled to VSS. Column 212 has a high write bit line labeled “WBLH” crossing all of cells 222, 224, and 226. Column 214 has a low write bit line labeled “WBLL” crossing all of cells 228, 230, and 232.

A row of reference cells 206 includes cells 220, 226, 232, and 238 each having gates coupled to a reference read word line labeled “RWLR”. However, only cells 226 and 232 are used as the high and low references during a read operation for any of the memory cells of the array. The reference row is activated for every read operation. The other cells of the row, such as cells 220 and 238 are disabled by disconnecting the select transistor from the MJT. For example, in FIG. 3, cell 220 has a select transistor 223 disconnected from a MJT 225 at location 221. Likewise, cell 238 has a select transistor 249 disconnected from MJT 251 at location 253. Also, as illustrated in FIG. 3, all of the cells of column 212 are disabled except for reference cell 226, and all of the cells of column 214 are disabled except for reference cell 232. Cell 222 is disabled by disconnecting select transistor 227 from MJT 229 at location 231. Cell 224 is disabled by disconnecting select transistor 231 from MJT 233 at location 235. Cell 228 is disabled by disconnecting select transistor 237 from MJT 239 at location 241. Cell 230 is disabled by disconnecting select transistor 243 from MJT 245 at location 247.

The disabled transistors, also referred to as “dummy cells”, still serve to provide capacitance to the bits lines and to the reference bit lines. The dummy MRAM cells do not provide a resistance to the data bit lines in response to enabling the reference word line. The presence of the dummy cells insures the bit line capacitance is the same for each bit line because each bit line has the same number of devices attached to it. The difference in resistance between a logic high state and a logic low state can be very small, on the order of only a few percent. Therefore, balancing the capacitance of the bit lines can be important for reliable sensing. Because the reference cells are not subjected to the write currents of other transistors of the row, the reference cells cannot be inadvertently toggled.

Before the array will operate, a logic state must be written to both of the reference cells 226 and 232. A high or low logic state is written to the reference cells only once. For example, a logic high state is written to reference cell 226 and a logic low state is written to reference cell 232. Generally, a logic state would be written to the reference cells during manufacturing. Therefore, the reference write word line WWLR would not be activated under normal use of the memory array.

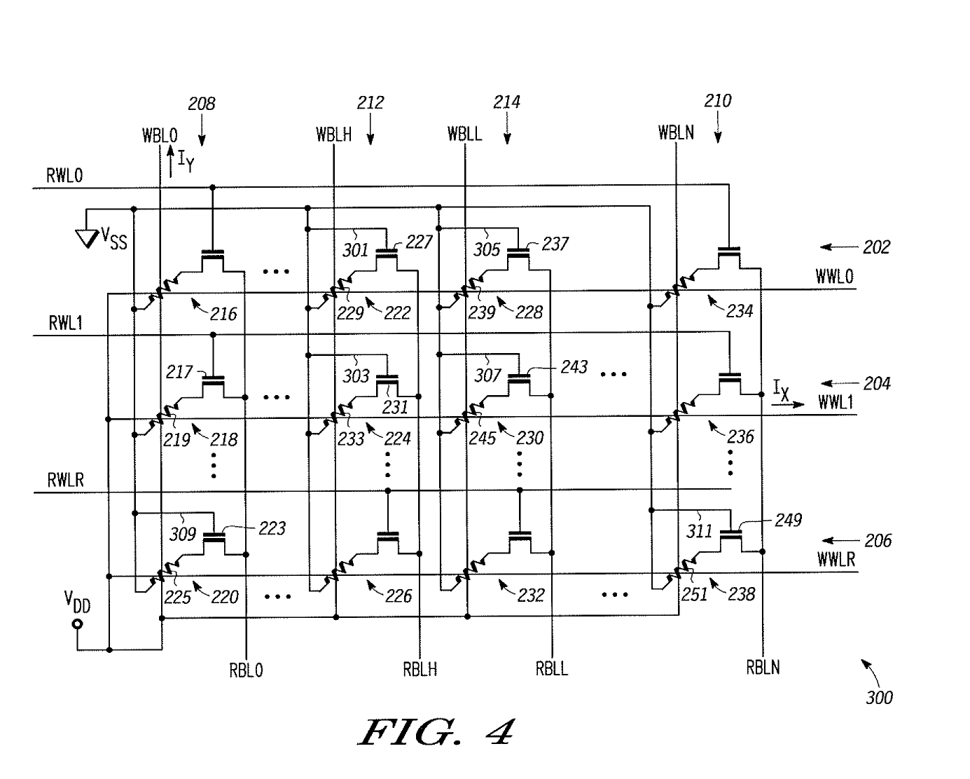

FIG. 4 illustrates, in schematic diagram form, MRAM array 300 in accordance with another embodiment of the present invention. MRAM array 300 is identical to MRAM 200 of FIG. 3 except that select transistors 223, 227, 231, 237, 243, and 249 are disabled by coupling their gates to ground (VSS). For example, in cell 220 gate electrode 309 of transistor 223 is not connected to read word line RWLR but is coupled to ground (VSS). In cell 222 gate electrode 301 of transistor 227 is not connected to read word line RWL0 but is coupled to ground (VSS). In cell 224 gate electrode 303 of transistor 231 is not connected to read word line RWL1 but is coupled to ground (VSS). In cell 228 gate electrode 305 of transistor 237 is not connected to read word line RWL0 but is coupled to ground (VSS). In cell 230 gate electrode 307 of transistor 243 is not connected to read word line RWL1 but is coupled to ground (VSS). In cell 238 gate electrode 311 of transistor 249 is not connected to read word line RWLR but is coupled to ground (VSS). The embodiment of FIG. 4 provides the same advantages of preventing the reference cells from being inadvertently toggled while maintaining balanced bit line capacitance.

In the embodiments of FIG. 3 and FIG. 4, the reference cell row 206 is the last row in the array and the corresponding columns 212 and 214 are near the middle of the array. In other embodiments the reference cell row and corresponding columns may be located elsewhere in the array.

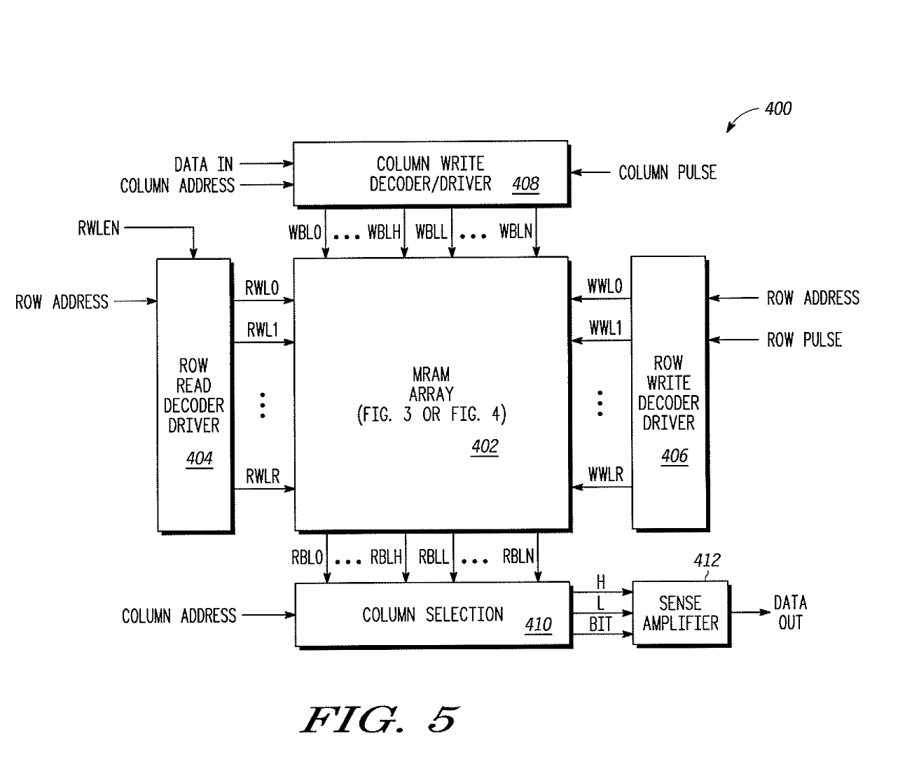

FIG. 5 illustrates, in block diagram form, a MRAM 400 having the MRAM array of FIG. 3 or FIG. 4. MRAM 400 includes an array of memory cells 402, a row read decoder driver 404, a row write decoder driver 406, a column write decoder driver 408, a column selection circuit 410, and a sense amplifier 412. MRAM array 402 includes a plurality of cells arranged in rows and columns. In one embodiment, array 402 includes the array 200 of FIG. 3. In another embodiment, array 402 includes the array 300 of FIG. 4. The read and write operations for the arrays of FIG. 3 and FIG. 4 are identical. The operation of MRAM 400 will be described with reference to FIG. 1 and FIG. 5.

In operation, a row address labeled “ROW ADDRESS” is provided to row read decoder driver 404 and to row write decoder driver 406. A column address labeled “COLUMN ADDRESS” is provided to column write decoder driver 408 and to column selection circuit 410. A control signal labeled “COLUMN PULSE” is provided to an input terminal of column write decoder/driver 408 and a control signal labeled “ROW PULSE” is provided to an input terminal of row write decoder driver 406. After the addresses are decoded and a data word line selected, and if the operation is a read operation, a read word line enable signal RWLEN is asserted and the selected data word line and the reference word line RWLR are simultaneously asserted in response. The column selection circuit 410 selects one of the read bit lines RBL0-RBLN based of the received column address COLUMN ADDRESS. The reference bit lines RBLH and RBLL are selected for every read operation. In response to the reference bit lines RBLH and RBLL being coupled to the column selection circuit 410, the column selection circuit 410 will provide a signal labeled “H” from the high resistance reference bit that is representative of the reference bit line current from RBLH to one input of sense amplifier 412. Also, a signal from a low resistance reference bit labeled “L”, that is representative of the reference bit line signal from RBLL, is provided by the column selection circuit 410 to a second input of sense amplifier 412. Finally, a signal representative of the logic state of the selected read bit line labeled “BIT” is provided to sense amplifier 412. In the illustrated embodiment, the signals are provided substantially simultaneously to sense amplifier 412. The sense amplifier 412 will compare the selected read bit line logic state to the high and low references and provide a data signal labeled “DATA OUT”. The data signal DATA OUT may be provided to, for example, a data processor (not shown). A sense amplifier circuit suitable for use with MRAM 400 is disclosed in U.S. Pat. No. 6,600,690, Nahas et al., incorporated herein by reference.

During a write operation, the row write decoder driver 406 will select one of the write word lines WWL0-WWL1 bases on the ROW ADDRESS. Note that only two write word lines WWL0 and WWL1 and two read word lines RWL0 and RWL1 are illustrated for discussion purposes only and are representative of the write word lines and read word lines in the memory array 402. There will be many more write word lines and read word lines in an actual memory. Still referring to FIG. 5, the column write decoder driver 408 will select a write bit line based on the COLUMN ADDRESS. A data input signal labeled “DATA IN” to be written to the array is also provided to column write decoder driver 408. As discussed above, the reference cells are written to only once in order to set their high and low logic states via reference write bit lines WBLH and WBLL and reference write word line WWRL. An end user of MRAM 400 would not be able to separately select the reference cells. The current pulses I_{X} and I_{Y} are provided to the selected cell as illustrated in FIG. 1. At time t0 of FIG. 1 there is no current through any write lines. After time to the current pulse I_{X} is initiated by signal ROW PULSE. At time t1 the I_{X} pulse is stable. After time t1 the current pulse I_{Y} is initiated by signal COLUMN PULSE if DATA IN is asserted. If DATA IN is not asserted, current pulse I_{Y} is not initiated. At time t2, both I_{Y} and I_{X} are both stable. The current I_{X} is removed after time t2 and current I_{Y} is removed after time t3 if it had been initiated. The write operation is ended at time t4 when both I_{X} and I_{Y} are off and the cell has been toggled. Note that the current sequence for writing to a cell may be different in other embodiments.

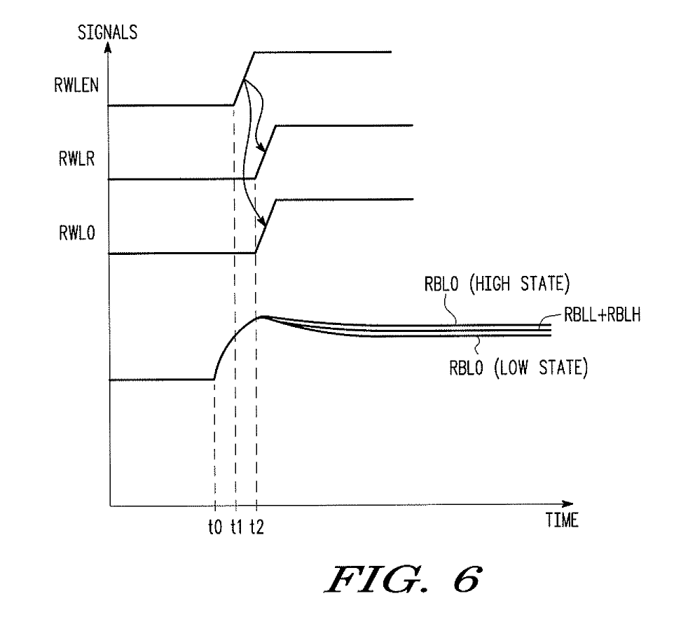

FIG. 6 illustrates a timing diagram of various signals in MRAM 400 of FIG. 5 useful for describing a read operation. At time to, the read bit lines are set at ground and then pulled to a predetermined precharge voltage. A read operation is initiated at time t1 by asserting the read word line enable signal RWLEN. The row decoder/driver circuit 404 of FIG. 5 is coupled to the reference read word line RWLR and the plurality of data word lines for simultaneously initiating an enablement of a selected data word line and the read reference word line in response to the enable signal RWLEN. In FIG. 6, the reference word line RWLR is asserted simultaneously with a selected one of the read word lines, for example RWL0 in response to enable signal RWLEN. After time t2, the read bit line voltage will resolve to either a high or low voltage relative the references RBLL+RBLH as illustrated. It is important that the reference word line and the selected read word line be initiated simultaneously or nearly simultaneously. As illustrated in FIG. 6 between time t0 and time t2 it is difficult to completely stabilize bit line precharge prior to beginning a read access during high speed read operations. Because of the very small voltage differences involved, the reference bit line and the selected data bit line should have the same response characteristics because no voltages can be truly stationary during high speed accessing. Therefore, separation between the reference and the selected bit line can be maintained more accurately by matching capacitance on the data bit lines and reference bit line as closely as possible and simultaneously selecting the data bit line and reference bit line.

Various changes and modifications to the embodiments herein chosen for purposes of illustration will readily occur to those skilled in the art. For example, variations in the types of conductivities of transistors, the types of transistors, etc. may be readily made. Although specific logic circuits have been shown, numerous logic circuit implementations may be used to implement the functions discussed herein. To the extent that such modifications and variations do not depart from the spirit of the invention, they are intended to be included within the scope thereof which is assessed only by a fair interpretation of the following claims.

What is claimed is:

1. A magnetoresistive random access memory (MRAM), comprising:
a memory array, comprising:
a plurality of data rows of MRAM cells;
a reference row of MRAM cells;
a plurality of data columns of MRAM cells;
a first reference column of MRAM cells;
a plurality of data word lines along the plurality of data rows;
a plurality of data bit lines along the plurality of data columns;
a first reference bit line along the first reference column; and
a reference word line along the reference row;
a column selection circuit coupled to the first reference bit line and the plurality of data bit lines; and
a row decoder/driver circuit coupled to the reference word line and the plurality of data word lines for simultaneously initiating an enablement of a selected data word line and the first reference word line.

2. The MRAM of claim 1, further comprising a sense amplifier coupled to the column selection circuit, wherein the column selection circuit selects a data bit line and couples the selected bit line and the first reference bit line to the sense amplifier.

3. The MRAM of claim 1, wherein the reference row of MRAM cells comprises a plurality of dummy MRAM cells and a first reference MRAM cell coupled to the first reference bit line and the reference word line.

4. The MRAM of claim 3, wherein:
the memory array further comprises a second reference column of MRAM cells and a second reference bit line along the second reference column; and
the column selection circuit is coupled to the second reference bit line and is further characterized as coupling the second reference bit line to the sense amplifier.

5. The MRAM of claim 4, wherein the first reference MRAM cell is written to a first logic state and provides a resistance representative of the first logic state in response to enablement of the reference word line and the second reference MRAM cell is written to a second logic state and provides a resistance corresponding to the second logic state in response to enablement of the reference word line.

6. The MRAM of claim 5, wherein the dummy MRAM cells do not provide a resistance to the plurality of data bit lines in response to enablement of the reference word line.

7. The memory of claim 5, wherein the dummy MRAM cells are not coupled to the reference word line.

8. The memory of claim 5, wherein:
the dummy MRAM cells comprise transistors and metal tunnel junctions;
the magnetic tunnel junctions are coupled to a first power supply terminal; and
the dummy MRAM cells are disabled by having the transistors not coupled to the first power supply terminal.

9. A method of operating a magnetoresistive random access memory (MRAM), wherein the MRAM comprises a memory array comprising:
a plurality of data rows of MRAM cells;
a reference row of MRAM cells;
a plurality of data columns of MRAM cells;
a first reference column of MRAM cells;
a plurality of data word lines along the plurality of data rows;
a plurality of data bit lines along the plurality of data columns;
a first reference bit line along the first reference column; and
a reference word line along the reference row;
the method comprising:
selecting a data word line of the plurality of data word lines to identify a selected data word line; and
simultaneously initiating enablement of the selected word line and the reference word line.

10. The method of claim 9, wherein:
a reference MRAM cell of the reference row of MRAM cells is coupled to the reference word line and the first reference bit line; and
the step of simultaneously initiating enablement is further characterized as providing a resistance representative of a logic state of the reference MRAM cell to the first reference bit line.

11. The method of claim 10, wherein:
the reference row of MRAM cells is further characterized as further comprising a plurality of row dummy MRAM cells;
the dummy MRAM cells are disabled so that the step of simultaneously initiating enablement does not provide resistances representative of logic states of the row dummy MRAM cells on the data bit lines.

12. The method of claim 10, wherein:
the reference column of MRAM cells is further characterized as further comprising a plurality of column dummy MRAM cells; and
the column dummy MRAM cells are disabled so that the step of simultaneously initiating enablement does not provide resistances representative of logic states of the column dummy MRAM cells on the first reference bit line.

13. The method of claim 9, wherein the step of simultaneously initiating enablement is in response to a row enable signal.

14. The method of claim 9, wherein:
the memory array further comprises a second reference column of MRAM cells and a second reference bit line along the second reference column;
the reference row of MRAM cells comprises:
a first reference cell that is written to a first logic state and is coupled to the reference word line and the first reference bit line; and
a second reference cell that is written to a second logic state and is coupled to the reference word line and the second reference bit line; and
the step of simultaneously initiating enablement is further characterized as providing a resistance representative of the first logic state to the first reference bit line and providing a resistance representative of the second logic state on the second reference bit line.

15. A magnetoresistive random access memory (MRAM), comprising:
a memory array, comprising:
a plurality of data rows of MRAM cells;
a reference row of MRAM cells comprising a first plurality of dummy MRAM cells and a first reference MRAM cell;
a plurality of data columns of MRAM cells;
a first reference column of MRAM cells comprising a second plurality of dummy MRAM cells and the first reference MRAM cell;
a plurality of data word lines along the plurality of data rows;
a plurality of data bit lines along the plurality of data columns;
a first reference bit line along the first reference column coupled to the first reference MRAM cell; and
a reference word line along the reference row coupled to the first reference MRAM cell;
a column selection circuit coupled to the first reference bit line and the plurality of data bit lines; and
a row decoder/driver circuit coupled to the reference word line and the plurality of data word lines that generates, substantially simultaneously, a data word line signal on a selected data word line and a reference word line signal on the reference word line in response to a word line enable signal.

16. The MRAM of claim 15, further comprising a sense amplifier coupled to the column selection circuit, wherein the column selection circuit selects a data bit line and couples the selected bit line and the first reference bit line to the sense amplifier.

17. The MRAM of claim 15, wherein the first reference MRAM cell provides a resistance to the first reference bit line in response to the reference word line signal.

18. The MRAM of claim 15, wherein:
the first reference MRAM cell is written to a first logic state provides a resistance representative of the first logic state in response to enablement of the reference word line;
the memory array further comprises a second reference column of MRAM cells and a second reference bit line along the second reference column;
the second reference column comprises a third plurality of dummy MRAM cells and a second reference MRAM cell coupled to the reference word line and the second reference bit line;
the second reference MRAM cell is written to a second logic state and provides a resistance representative of the second logic state in response to enablement of the reference word line;
the reference row further comprises the second reference MRAM cell; and
the column selection circuit is coupled to the second reference bit line and is further characterized as coupling the second reference bit line to the sense amplifier.

19. The MRAM of claim 15, wherein the dummy MRAM cells of the first and second plurality of dummy MRAM cells are disabled.

20. The memory of claim 15, wherein the MRAM dummy cells of the first plurality of dummy MRAM cells of the dummy row are not connected to the reference word line.
